(19) United States
(12) Patent Application Publication
(10) Pub. No.: US 2025/0327855 A1
(43) Pub. Date: Oct. 23, 2025

(54) SHEET CONTACTOR SOCKET

(71) Applicant: YOKOWO CO., LTD., Tokyo (JP)

(72) Inventors: Ryota SAKAUCHI, Gunma (JP); Yuki MATSUI, Gunma (JP)

(73) Assignee: YOKOWO CO., LTD., Tokyo (JP)

(21) Appl. No.: 19/185,319

(22) Filed: Apr. 22, 2025

(30) Foreign Application Priority Data
Apr. 23, 2024 (JP) 2024-069498

(51) Int. Cl. G01R 31/28

(52) U.S. Cl. CPC G01R 31/2863; G01R 31/2867; G01R 31/2879; G01R 31/2887; G01R 31/2891

(57) ABSTRACT

A sheet contactor socket, includes: a plate positioned on an upper side of a sheet contactor having contact terminals and having an accommodation portion that is able to accommodate a semiconductor package having contact portions in contact with the contact terminals, respectively; and a cover elastically supports the plate. The accommodation portion includes: a placement portion on which the semiconductor package is able to be placed and that has a guiding portion that guides the contact portions to a position where the contact portions and the contact terminals are able to be brought into contact with each other; and a non-placement portion on which the semiconductor package is not placed. A placement region of the placement portion in the accommodation portion is smaller than a non-placement region of the non-placement portion on which the semiconductor package is not placed.

### CROSS-REFERENCE TO RELATED APPLICATION(S)

This application is based on and claims priority under 35 USC 119 from Japanese Patent Application No. 2024-069498, filed on Apr. 23, 2024, the contents of which is incorporated herein by reference.

### TECHNICAL FIELD

The present invention relates to a sheet contactor socket.

### BACKGROUND ART

The inspection of a semiconductor package is performed by bringing a large number of pins of the semiconductor package into contact with an energizing portion of an inspection socket.

The inspection socket includes an energizing portion for inspection, a plate on which the semiconductor package is placed, and a cover supporting the plate, and at the time of inspection, the semiconductor package is placed on the plate by a handler device or the like, and then the semiconductor package and the energizing portion are brought into contact with each other.

As the energizing portion of this kind of inspection socket, a contact probe including a minute spring and a plunger as described in Patent Literature 1 and a sheet contactor in which a contact terminal is disposed on a sheet as described in Patent Literature 2 are known.

### CITATION LIST

### Patent Literature

Patent Literature 1: JP2023-036137A
Patent Literature 2: JP2000-030828A

When the semiconductor package is inspected, the semiconductor package may be dropped and placed on the plate. In this case, the semiconductor package is required to be placed at an appropriate position on the plate.

### SUMMARY

An object of the present invention is to provide a sheet contactor socket in which a semiconductor package is placed at an appropriate position when the semiconductor package is placed on a plate. Other objects of the present invention will become apparent based on the present description.

A sheet contactor socket according to an aspect of the present invention includes:
a plate positioned on an upper side of a sheet contactor having a plurality of contact terminals and having an accommodation portion that is able to accommodate a semiconductor package having a plurality of contact portions in contact with the plurality of contact terminals, respectively; and a cover configured to elastically support the plate, in which
the accommodation portion includes: a placement portion on which the semiconductor package is able to be placed and that has a guiding portion that guides contact portions of the plurality of contact portions to a position where the plurality of contact portions and the plurality of contact terminals are able to be brought into contact with each other; and a non-placement portion on which the semiconductor package is not placed, and
a placement region of the placement portion in the accommodation portion is smaller than a non-placement region of the non-placement portion on which the semiconductor package is not placed.

### BRIEF DESCRIPTION OF DRAWINGS

FIG. 1A is an exploded perspective view of an embodiment of a sheet contactor socket 100.

FIG. 1B is a perspective view of a state in which the sheet contactor socket 100 of FIG. 1A is assembled.

FIG. 1C is an exploded perspective view illustrating the fixation of the sheet contactor socket 100 to a stiffener 80.

FIG. 2 is a plan view of an embodiment of a sheet contactor 10.

FIG. 3A is a cross-sectional view of an embodiment of a support portion of a cover 30 that elastically supports a plate 20.

FIG. 3B is a cross-sectional view of the embodiment of the support portion of the cover 30 that elastically supports the plate 20, and illustrates the support portion in a different state from that in FIG. 3A.

FIG. 3C is a conceptual diagram illustrating that a first guide portion 21b guides an electrode 210 of a semiconductor package 200.

FIG. 3D is a conceptual diagram illustrating that the first guide portion 21b guides the electrode 210 of the semiconductor package 200.

FIG. 4A is a plan view of an embodiment of the plate 20.

FIG. 4B is an enlarged view of an embodiment of a placement portion 21 and a second guide portion 24 of the plate 20 of FIG. 4A.

FIG. 5A is a cross-sectional view of an embodiment of the sheet contactor socket 100 in a state in which the semiconductor package 200 is placed on the plate 20.

FIG. 5B is a cross-sectional view of the embodiment of the sheet contactor socket 100 in the state in which the semiconductor package 200 is placed on the plate 20, and illustrates the sheet contactor socket 100 in a different state from that in FIG. 5A.

FIG. 5C is an enlarged view illustrating contact portions between the electrodes 210 of the semiconductor package 200 of FIG. 5B and contact terminals 11 of the sheet contactor 10.

### DESCRIPTION OF EMBODIMENTS

The present invention will be specifically described with reference to the following embodiments, but the present invention is not limited thereto. When there is no particular detailed reference to each device, mechanism, means, and the like described in the present specification, those skilled in the art can use known mechanical devices, mechanisms, means, and the like. The respective embodiments can be combined based on ordinary knowledge by those skilled in the art, and configurations not specifically described in the respective embodiments can have the same configurations as the other embodiments or configurations suitable for the embodiments. In a cross-sectional view, a cross section of each member is represented by various oblique lines for easy discrimination from other members, but a difference in oblique lines does not represent a difference in material, shape, or the like of the member.

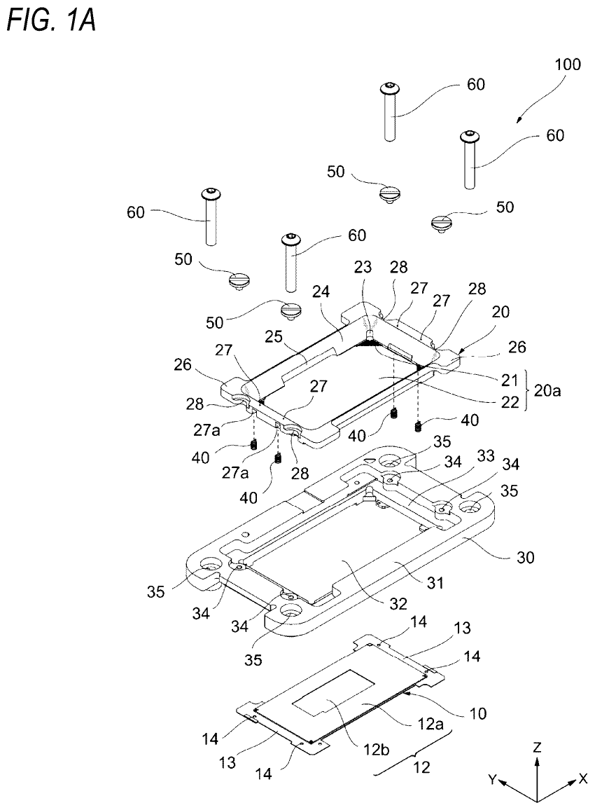

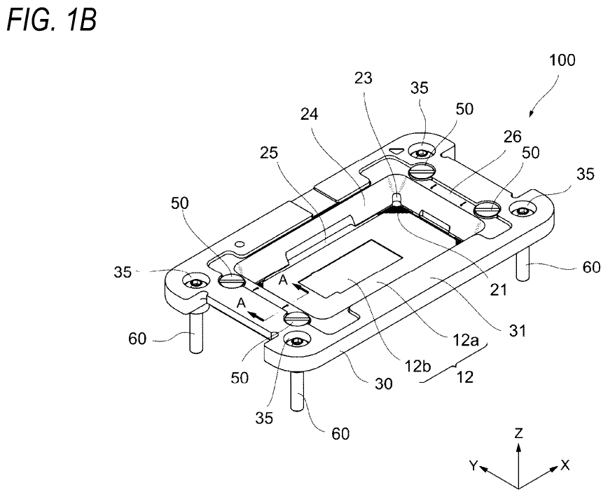

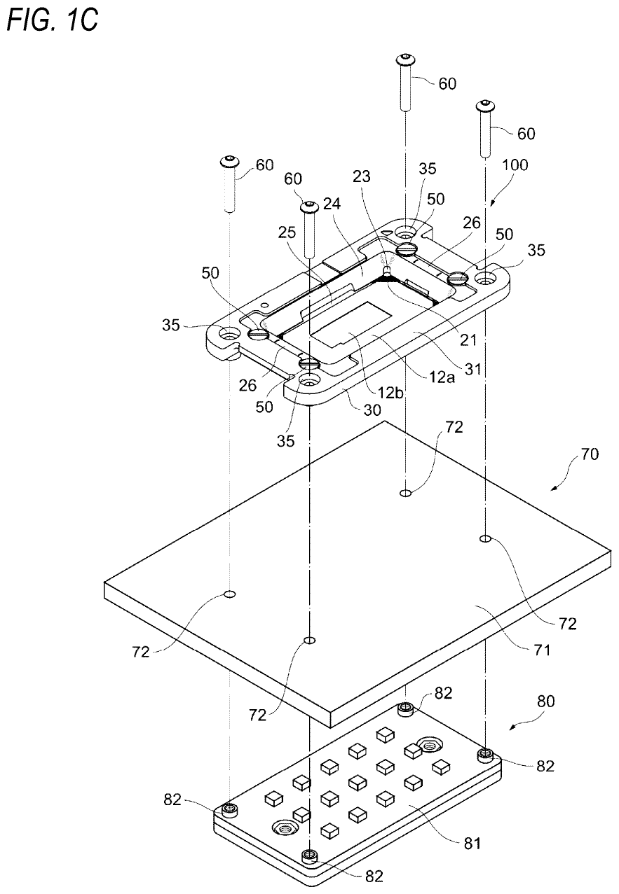

In order to describe directions, an X direction, a Y direction, and a Z direction are defined. The X direction is one of directions perpendicular to a thickness direction of a sheet contactor socket 100. The Y direction is one of the directions perpendicular to the thickness direction of the sheet contactor socket 100 and the X direction. The Z direction is the thickness direction of the sheet contactor socket 100. In the present embodiment, the X direction is a front-rear direction of a sheet contactor 10, the Y direction is a left-right direction of the sheet contactor 10, and the Z direction is an upper-lower direction. In FIG. 1 and the like, a direction indicated by an X-axis arrow is defined as a front direction, a direction indicated by a Y-axis arrow is defined as a left direction, and a direction indicated by a Z-axis arrow is defined as an upper direction.

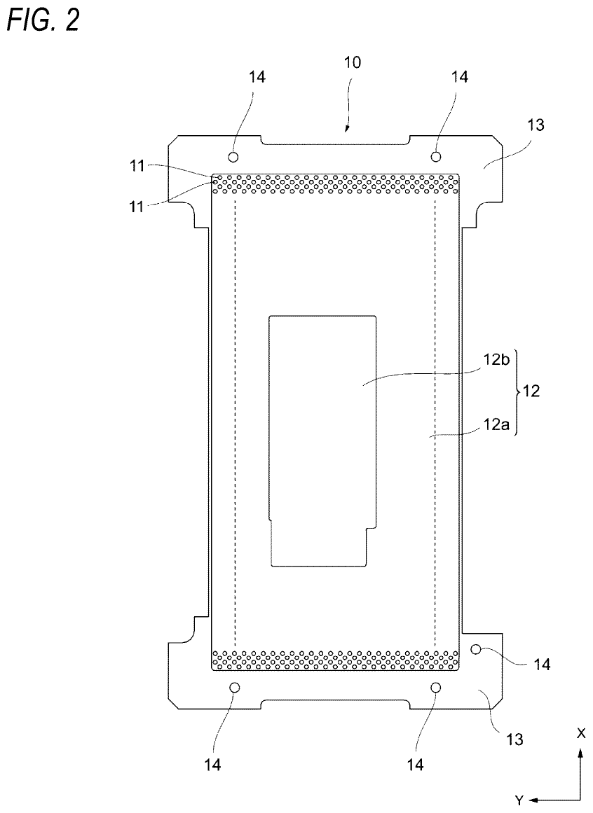

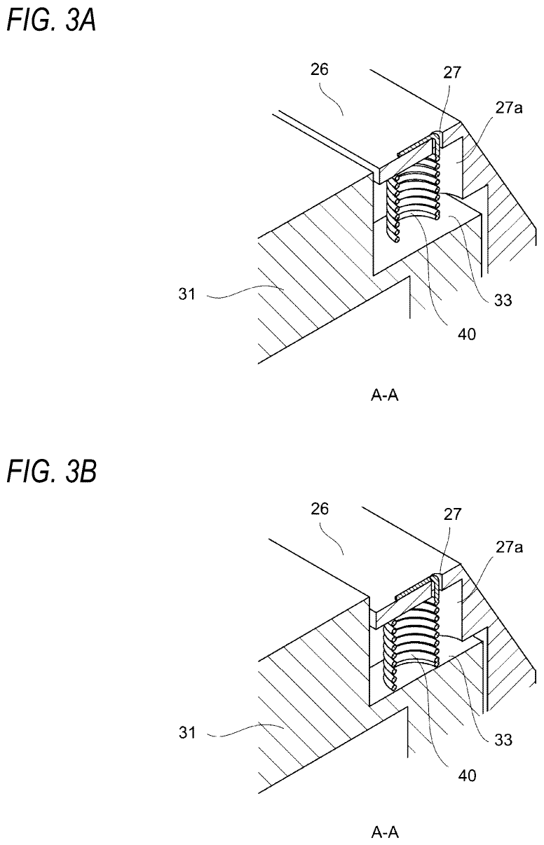

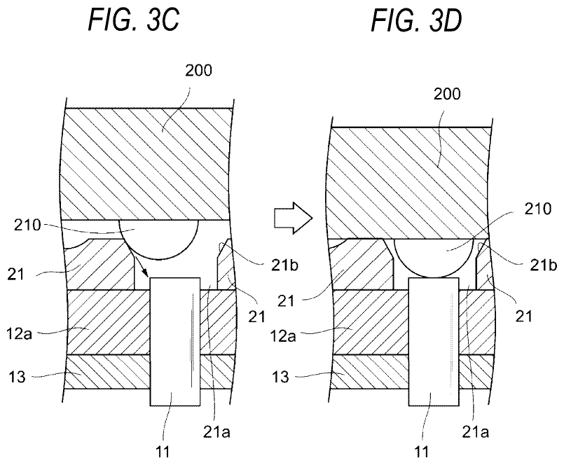

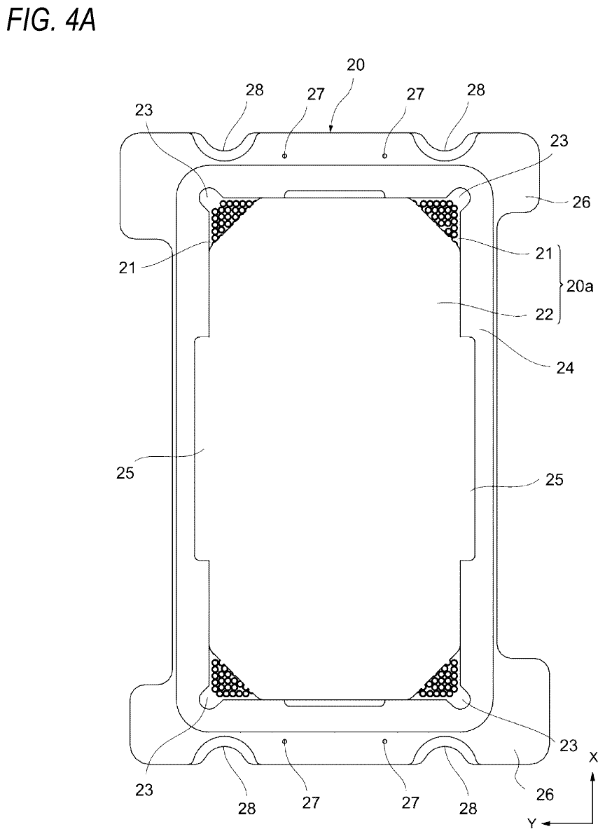

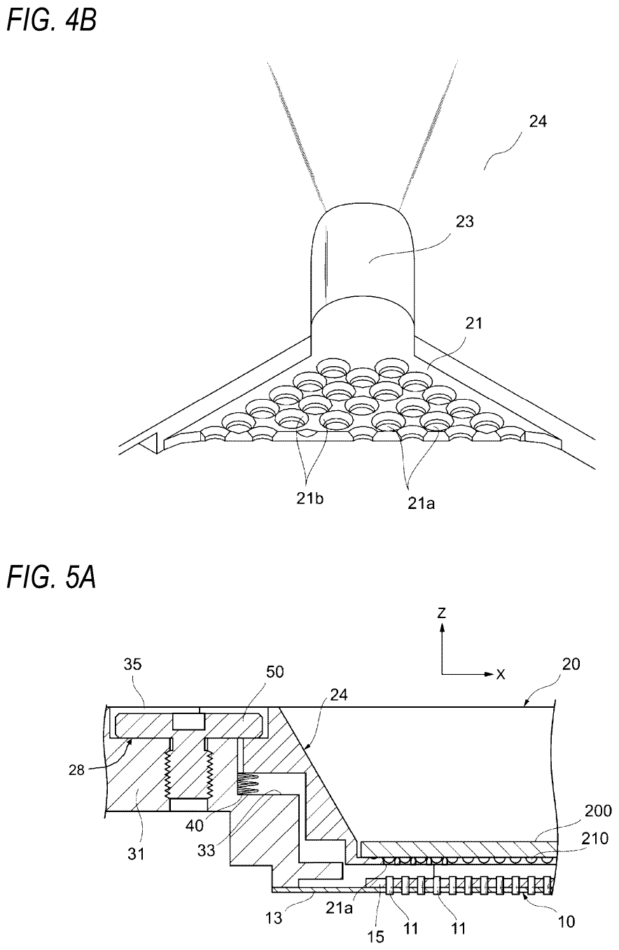

A configuration of the sheet contactor socket 100 according to the present embodiment will be described with reference to FIGS. 1A to 1C, 2, 3A to 3D, 4A, and 4B. FIG. 1A is an exploded perspective view of the sheet contactor socket 100 according to the present embodiment. FIG. 1B is a perspective view of the sheet contactor socket 100 of FIG. 1A in an assembled state. FIG. 1C is an exploded perspective view illustrating the fixation of the sheet contactor socket 100 to a stiffener 80. FIG. 2 is a plan view of the sheet contactor 10 in the present embodiment. FIG. 3A is a cross-sectional view taken along a line A-A of the sheet contactor socket 100 of FIG. 1B in the present embodiment, and is a view illustrating a support portion of a cover 30 that elastically supports a plate 20. FIG. 3B is a cross-sectional view taken along the line A-A of the sheet contactor socket 100 of FIG. 1B in the present embodiment, and illustrates a state different from that of FIG. 3A of the support portion of the cover 30 that elastically supports the plate 20. FIGS. 3C and 3D are conceptual diagrams illustrating how a first guide portion 21b guides an electrode 210 of a semiconductor package 200. FIG. 4A is a plan view of the plate 20 in the present embodiment. FIG. 4B is an enlarged view of a placement portion 21 and a second guide portion 24 of the plate 20 of FIG. 4A.

As illustrated in FIGS. 1A and 1B, the sheet contactor socket 100 includes the sheet contactor 10, the plate 20, and the cover 30. In the present embodiment, the sheet contactor socket 100 including the sheet contactor 10, the plate 20, and the cover 30 will be described, but the sheet contactor socket 100 may include the plate 20 and the cover 30 excluding the sheet contactor 10. In the present embodiment, the sheet contactor socket 100 includes four spring members 40 between the plate 20 and the cover 30. The sheet contactor socket 100 includes four pressing members 50 for pressing the plate 20 against the cover 30. Further, in the present embodiment, as illustrated in FIG. 1C, the sheet contactor socket 100 includes four fixing members 60 for fixing the cover 30 to the stiffener 80 via a substrate 70.

As illustrated in FIGS. 1A, 1B, and 2, the sheet contactor 10 includes the plurality of contact terminals 11, a sheet body 12, sheet base material portions 13, and a plurality of sheet fixing portions 14. The sheet body 12 includes a support region 12a in which the plurality of contact terminals 11 are arranged and supported, and a non-support region 12b that is opened and in which the contact terminals 11 are not supported. As illustrated in FIG. 2, the plurality of contact terminals 11 are arranged in close contact with each other over substantially the entire region of the support region 12a.

In order to inspect electrical characteristics of the semiconductor package 200, the plurality of contact terminals 11 are brought into contact with the plurality of electrodes 210 corresponding to the contact portions provided in the semiconductor package 200 illustrated in FIGS. 3C and 3D and energized. In FIGS. 1A and 1B, illustration of the contact terminals 11 is omitted. In FIG. 2, only some of the contact terminals 11 are illustrated, and the arrangement of the contact terminals 11 in the support region 12a is partially omitted. The non-support region 12b is an opening provided at the center of the support region 12a, and the contact terminals 11 are not provided. The non-support region 12b corresponds to a region where the electrodes 210 are not provided in the semiconductor package 200. Each of the plurality of contact terminals 11 arranged in the support region 12a corresponds to each of the plurality of electrodes 210 of the semiconductor package 200 in a one-to-one correspondence. Each of the plurality of contact terminals 11 is disposed at a position facing each of the plurality of electrodes 210 of the semiconductor package 200 when the semiconductor package 200 is placed on the plate 20.

In the plurality of contact terminals 11, for example, conductive particles such as metal are supported by a resin such as a silicone resin. The form of the plurality of contact terminals 11 is not particularly limited as long as the contact terminals 11 can be brought into contact with the electrodes 210 of the semiconductor package 200 and energized. A protrusion amount of the contact terminal 11 in the upper direction from the sheet contactor 10 is limited. In consideration of guiding each of the plurality of electrodes 210 to an appropriate position for being brought into contact with each of the plurality of contact terminals 11, it is desirable to provide a configuration for guiding the plurality of electrodes 210 to the plurality of contact terminals 11, respectively.

However, since the protrusion amount of the plurality of contact terminals 11 in the upper direction from the sheet contactor 10 is limited, it is difficult to increase the thickness of the plate 20 in the upper direction. Further, when a configuration for guiding each of the plurality of contact terminals 11 is provided in a state in which the thickness of the plate 20 is not increased, a defect such as warpage due to processing of the plate 20 may occur. In the present embodiment, each of the plurality of electrodes 210 can be guided to the appropriate position for being brought into contact with each of the plurality of contact terminals 11 without increasing the thickness of the plate 20.

Further, in the sheet contactor 10 of the present embodiment, for example, when a force is applied from a lower side, metal particles come into contact with each other in the sheet contactor 10 for the first time and can be energized. Further, compared to the case where a contact probe that is expandable and contractible in the Z direction is used, the length of the contact terminal 11 in the Z direction can be made very small, resulting in a shorter transmission distance and reduced loss at high frequencies. Accordingly, an energization inspection of the semiconductor package 200 can be performed at a higher frequency. In the present embodiment, the plurality of electrodes 210 provided in the semiconductor package 200 have a substantially hemispherical shape protruding in the lower direction.

The sheet body 12 has substantially the same shape as a planar shape of the semiconductor package 200, and has a substantially quadrilateral shape including two sides extending in the X direction and two sides extending in the Y direction. The sheet body 12 may not have substantially the same shape as the semiconductor package 200 as long as each of the plurality of contact terminals 11 can come into contact with each of the plurality of electrodes 210 of the semiconductor package 200.

The sheet base material portion 13 includes sheet fixing portions 14. The sheet base material portion 13 is provided along each of two sides extending in the Y direction of the sheet body 12 in FIG. 2. As illustrated in FIG. 2, the sheet fixing portions 14 are holes penetrating in the Z direction at a plurality of positions of the sheet base material portion 13, and in the present embodiment, two sheet fixing portions 14 are provided at an interval in the Y direction. The sheet contactor 10 is attached to the cover 30 or the like by passing screws or the like through the holes of the sheet fixing portions 14 from a lower side toward the upper direction of the cover 30.

The plate 20 is a member positioned on the upper side of the sheet contactor 10 and the cover 30 and placed on the cover 30. As illustrated in FIGS. 1A, 1B, 4A, and 4B, the plate 20 includes placement portions 21, through holes 21a, first guide portions 21b, an opening 22, chamfered portions 23, the second guide portion 24, perforated portions 25, plate outer peripheral portions 26, locking portions 27, and pressing portions 28. Here, the combination of the placement portion 21 and the opening 22 is a region for accommodating the semiconductor package 200, and constitutes an accommodation portion 20a in the present invention.

The accommodation portion 20a is a portion that accommodates the semiconductor package 200 inside the plate 20. In the present embodiment, an example in which the accommodation portion 20a, which is a combination of the placement portion 21 and the opening 22, has a substantially quadrilateral shape is illustrated, but the specific shape is not limited as long as it corresponds to an outer shape of the semiconductor package 200. In the example illustrated in FIG. 4A, the accommodation portion 20a has a size substantially equal to the size of the semiconductor package 200.

The placement portion 21 is a portion including a placement region where the semiconductor package 200 can be placed. In order to guide each of the plurality of electrodes 210 of the semiconductor package 200 to a position where each of the plurality of electrodes 210 can come into contact with each of the plurality of contact terminals 11 of the sheet contactor 10, the placement portion 21 has the through holes 21a that guides a part of the plurality of electrodes 210 to a position where a part of the plurality of electrodes 210 can come into contact with a part of the plurality of contact terminals 11. The first guide portion 21b is provided around each of the plurality of through holes 21a. FIG. 4A illustrates an example in which the plate-shaped placement portions 21 are disposed at four corners of the opening 22, but the positions of the placement portions 21 are not limited, and the placement portions 21 may be disposed along each side of the opening 22. Each of the four placement portions 21 has a substantially triangular shape, and the plurality of through holes 21a and first guide portions 21b are arranged in the substantially triangular placement region.

It is more preferable that a plurality of through holes 21a and a plurality of first guide portions 21b are provided in one placement portion 21 than one through hole 21a and one first guide portion 21b are provided in at least one placement portion 21. Further, the size of the placement portion 21 is not limited, but the total area of the areas of the plurality of placement portions 21 is preferably smaller than the area of the opening 22.

In a socket using the contact probe as the contact terminal, since the contact probe can be expanded and contracted in the upper-lower direction and brought into contact with the electrode 210 of the semiconductor package 200, the plate 20 on which the semiconductor package 200 is placed can be thickened. However, when the sheet contactor 10 is used, it is necessary to reduce the thickness of the placement portion 21 of the plate 20 since the movement of the contact terminal 11 in the upper-lower direction or a height protruding upward from the sheet contactor 10 is limited. However, it has been found that when the placement portion 21 is formed over substantially the entire region of the plate 20 to reduce the thickness, distortion occurs when the through holes 21a are processed in the placement portion 21, and it is difficult to maintain the processing accuracy.

Therefore, in the sheet contactor socket 100 of the present embodiment, the placement portion 21 supporting the semiconductor package 200 is formed only in a part of the plate 20, and the electrode 210 of the semiconductor package 200 and the contact terminal 11 of the sheet contactor 10 can be connected to each other also in the opening 22.

As an example, the width in which the placement portion 21 is formed is preferably in a range of 1 mm or more and 100 mm or less in an X-Y plane from a lower end of the second guide portion 24. When the width of the placement portion 21 is less than 1 mm, it is difficult to place, properly position, and hold the semiconductor package 200. When the width of the placement portion 21 is larger than 100 mm, processing distortion is likely to occur when the through hole 21a or the first guide portion 21b is processed, which is not preferable. The thickness of the placement portion 21 is not limited, but is preferably in a range of 0.05 mm or more and 0.45 mm or less, and more preferably in a range of 0.2 mm or more and 0.3 mm or less. The area of the placement portions 21 of the plate 20 (the total area of the areas of the four placement portions 21 in the present embodiment) is preferably 0.1 times or less the area of the opening 22.

The through hole 21a is a hole formed to penetrate from an upper surface side to a lower surface side of the placement portion 21. As illustrated in FIG. 4A, each of the plurality of through holes 21a is disposed at an interval from the adjacent through hole 21a, and corresponds to the position of the electrode 210 of the semiconductor package 200. The shape of the through hole 21a is not limited, but is a shape that allows the electrode 210 to be positioned in the through hole 21a, and is a substantially cylindrical shape in the example illustrated in FIGS. 4A and 4B. An inner diameter of each of the plurality of through holes 21a is larger than an outermost diameter of the electrode 210 such that the electrode 210 that has the substantially hemispherical shape is inserted. As illustrated in FIG. 4B, first guide portions 21b are formed around the plurality of through holes 21a in the placement portion 21. Further, as illustrated in FIG. 4B, a part of the arranged through holes 21a and first guide portions 21b may be cut off by an outer edge of the placement portion 21.

The first guide portion 21b is a tapered portion that is formed by chamfering around each of the plurality of through holes 21a and is inclined such that the width decreases from the upper side to the lower side. An inclination angle of the first guide portion 21b is not limited, but the inclination angle may be an angle at which a force for moving the semiconductor package 200 in the X-Y plane can be applied when the electrodes 210 of the semiconductor package 200 come into contact with the first guide portions 21b. The first guide portion 21b has a shape similar to the shape of the through hole 21a, and a center of the through hole 21a substantially coincides with a center of the first guide portion 21b. As described later, the first guide portion 21b has a function of guiding the semiconductor package 200 transferred onto the plate 20 and dropped toward the plate 20 into the through hole 21a of the plate 20, and corresponds to one of guiding portions in the present invention. The first guide portion 21b can guide the semiconductor package 200 into the through hole 21a by using the inclination of the first guide portion 21b even when a drop direction of the semiconductor package 200 dropped toward the plate 20 is offset from the through hole 21a.

The opening 22 is an opening formed inside the plate 20. The opening 22 exposes the plurality of contact terminals 11 of the sheet contactor 10 in the plan view from above of the plate 20 with no semiconductor package 200 placed thereon. Therefore, the opening 22 is a region where the semiconductor package 200 is not placed, and corresponds to a non-placement portion in the present invention. In a state in which the semiconductor package 200 is placed on the plate 20, each of the plurality of electrodes 210 of the semiconductor package 200 is in contact with each of the plurality of contact terminals 11 exposed from the opening 22. The inspection substrate (not illustrated) is provided below the sheet contactor 10 and is electrically connected to each of the plurality of contact terminals 11 of the sheet contactor 10. The inspection substrate is electrically connected to each of the plurality of electrodes 210 of the semiconductor package 200 via each of the plurality of contact terminals 11. Then, the electrical characteristics of the semiconductor package 200 are inspected. Meanwhile, even in the opening 22 of the plate 20, since the contact terminals 11 and/or the electrodes 210 of the semiconductor package 200 are not present in the non-support region 12b of the sheet contactor 10, they are not in contact with each other. The non-support region 12b is, for example, a region provided to expose a part of a circuit in the inspection substrate, so it is not necessarily need to be provided.

The chamfered portion 23 is a groove formed in the vicinity of a corner portion of the accommodation portion 20a by cutting out a part of the second guide portion 24. As illustrated in FIG. 4B, the second guide portion 24 and the placement portion 21 constituting two sides of the quadrilateral shape intersect at the corner portion of the accommodation portion 20a. In this way, it is difficult to perform mechanical processing with high accuracy at the corner portion where two inclined surfaces and the plane intersect. However, in the present embodiment, since the chamfered portions 23 are formed at the four corners of the plate 20, the plate 20 can be easily processed.

The second guide portion 24 is a tapered portion formed on the plate 20 and inclined in an obliquely upper direction from the X-Y plane where the placement portion 21 and the opening 22 are present so as to expand to the outside of the plate 20. The second guide portion 24 has a substantially quadrilateral shape including two sides extending in the X direction and two sides extending in the Y direction. The second guide portion 24 has a function of guiding the semiconductor package 200 transferred onto the plate 20 and dropped toward the plate 20 into the accommodation portion 20a of the plate 20. The second guide portion 24 can guide the semiconductor package 200 into the accommodation portion 20a using the inclination of the second guide portion 24 even when the drop direction of the semiconductor package 200 dropped toward the plate 20 is offset in the front-rear direction or the left-right direction with respect to the accommodation portion 20a.

The perforated portion 25 is a portion on a lower side of the second guide portion 24 and cut out in a concave shape along the X direction at a substantially central portion of each of the two sides extending in the X direction of the plate 20. Since the perforated portion 25 is provided in the second guide portion 24, when the semiconductor package 200 placed on the plate 20 is gripped by tweezers, for example, during a hand test, tip ends of the tweezers are easily inserted between the side surface of the semiconductor package 200 and the second guide portion 24.

The plate outer peripheral portion 26 is a portion extending along each of two sides of plate 20 extending in the Y direction. The plurality of locking portions 27 and the plurality of pressing portions 28 are formed in the plate outer peripheral portion 26. As illustrated in FIG. 1A, the plate outer peripheral portion 26 is provided at a position facing a plate placement portion 33 of the cover 30 described later, and has a shape corresponding to an inner periphery of a frame portion 31. Therefore, in a state in which the plate 20 is placed on the cover 30, an outer periphery of the plate outer peripheral portion 26 is disposed along the inner periphery of the frame portion 31. Therefore, the plate 20 is disposed on the cover 30 in a state in which the movement in an XY in-plane direction is restricted and the plate 20 is movable in the upper-lower direction (Z direction).

The locking portions 27 are holes penetrating the plate outer peripheral portion 26 in the Z direction, and two locking portions 27 are provided at an interval in the Y direction of each plate outer peripheral portion 26. The locking portion 27 is used to lock one end of the spring member 40, and a diameter thereof is substantially the same as a wire diameter of the spring member 40. As illustrated in FIGS. 3A and 3B, at a position where the locking portion 27 is formed, a spring accommodation portion 27a is provided on a lower side of the plate outer peripheral portion 26.

The spring accommodation portion 27a is a recessed portion provided on a surface (lower side) of the plate outer peripheral portion 26 facing the plate placement portion 33, and is a space for accommodating the spring member 40. One end of the spring member 40 accommodated in the spring accommodation portion 27a is inserted into the locking portion 27 and is bent and locked on an upper surface of the plate outer peripheral portion 26. The shape and size of the spring accommodation portion 27a are not limited, but the spring accommodation portion 27a is preferably a recess slightly larger than an outer shape of the spring member 40. By disposing the spring accommodation portion 27a in the plate outer peripheral portion 26, the plate outer peripheral portion 26 can be thinned at a position where the locking portion 27 is formed, and the thickness of the plate outer peripheral portion 26 can be ensured at other portions to ensure the strength.

The pressing portion 28 is a portion that is formed on the plate outer peripheral portion 26 and in which the pressing member 50 for restricting the movement of the plate 20 in the upper direction is disposed. By disposing the pressing member 50 on the pressing portion 28, the plate 20 elastically supported by the spring member 40 is restricted from moving in the Z direction. Further, in one plate outer peripheral portion 26, two pressing portions 28 are recessed in an arc shape toward the front direction and provided at an interval along the Y direction. In the other plate outer peripheral portion 26, the two pressing portions 28 are recessed in an arc shape toward the rear direction and provided at an interval along the Y direction. The pressing portion 28 has a stepped shape, and a part of the pressing member 50 is disposed on an upper step portion thereof. Note that the positions at which the locking portions 27 and the pressing portions 28 are provided and the numbers thereof are not limited thereto.

The cover 30 is a member that elastically supports the plate 20 such that the plate 20 is movable in the Z direction by the spring member 40. As illustrated in FIG. 1A, the cover 30 elastically supports the plate 20 using four spring members 40. The number of spring members 40 is not limited thereto. As illustrated in FIGS. 1A and 1B, the cover 30 includes the frame portion 31, a cover opening 32, the plate placement portion 33, arrangement portions 34, and fixing holes 35.

In the present specification, “elastically supported” means that in order to place the semiconductor package 200 on the plate 20, when the semiconductor package 200 is dropped from above and brought into contact with the plate 20, the plate 20 is supported so that the impact applied to the semiconductor package 200 is reduced. This reduces the impact applied to the semiconductor package 200 as compared with the case where the cover 30 simply fixes and supports the plate 20 by screwing or the like. Examples of a configuration for implementing such elastic support include not only the spring member 40 but also an elastic body made of a soft material such as rubber. Further, the sheet contactor 10 is positioned and attached to the lower side of the cover 30, and the sheet contactor 10 and the plate 20 are relatively positioned via the cover 30.

The frame portion 31 is a frame-shaped member that forms an outer shape of the cover 30. As illustrated in FIGS. 1A, 1B, and 1C, the frame portion 31 is provided with the cover opening 32, the plate placement portion 33, the arrangement portions 34, and the fixing holes 35. The frame portion 31 accommodates the plate 20 so as to be movable in the Z direction in the cover opening 32, and is fixed to the stiffener 80 by the fixing members 60 via the substrate 70.

The cover opening 32 is an opening that penetrates the center of the cover 30 in the Z direction and is surrounded by the frame portion 31. As illustrated in FIG. 1B, the plate 20 is disposed from the cover opening 32, and the inside of the opening 22 of the plate 20 is exposed. Therefore, in the cover opening 32, the sheet contactor 10 disposed at a lower side of the plate 20 and the cover 30 is partially exposed, and the support region 12a and the non-support region 12b are exposed.

The plate placement portion 33 is a portion provided in the frame portion 31 around the cover opening 32 and formed in a stepped shape for placing the plate 20. As illustrated in FIG. 1A, the plate placement portion 33 is provided at a position one step lower than an upper surface of the frame portion 31 along the front-rear direction and the left-right direction so as to surround the cover opening 32. The contour of the plate placement portion 33 is substantially the same as an outer shape of the plate 20 and has a shape capable of accommodating the plate 20. In a state where the plate 20 is placed, the plate placement portion 33 faces a part of a back surface side of the plate 20. In the present embodiment, as illustrated in FIGS. 1A and 1B, the plate outer peripheral portion 26 and the plate placement portion 33 have a shape partially protruding in the left-right direction (Y direction). Accordingly, in the state in which the plate 20 is placed on the cover 30, the plate 20 can be positioned by restricting the movement of the plate 20 in the XY in-plane direction.

The arrangement portion 34 is a portion for disposing the pressing member 50 on the upper surface of the frame portion 31. A screw hole is formed in the arrangement portion 34, and the pressing member 50 is screwed and fixed. In the present embodiment, two arrangement portions 34 are provided on each of the front and rear of the cover 30 at positions corresponding to the pressing portions 28 of the plate 20. Further, the arrangement portion 34 has an arc-shaped recess directed in the front-rear direction and a substantially cylindrical portion protruding toward the plate placement portion 33. The substantially arc-shaped recess and the substantially cylindrical shape of the arrangement portion 34 have a shape and a size corresponding to a substantially concave shape that is a substantially arc shape of the pressing portion 28, and in the state in which the plate 20 is placed on the cover 30, the arrangement portion 34 and the pressing portion 28 are combined to form a substantially circular shape.

The fixing hole 35 is a hole that penetrates the frame portion 31 in the Z direction and into which the fixing member 60 is inserted from the upper direction. In the present embodiment, two fixing holes 35 are provided in the vicinity of the corner portions in each of the front and rear of the frame portion 31.

The spring member 40 is a spirally wound spring and disposed between the plate 20 and the plate placement portion 33 of the cover 30. The spring member 40 is accommodated in the spring accommodation portion 27a of the plate 20, and one end thereof penetrates the locking portion 27 formed in the plate outer peripheral portion 26. Then, the penetrating end is bent on the plate outer peripheral portion 26, so that the spring member 40 is locked to the plate 20. The other end of the spring member 40 is disposed to face the plate placement portion 33 of the cover 30, and comes into contact with the plate placement portion 33 when the plate 20 is placed on the cover 30. At this time, the plate placement portion 33 of the cover 30 and the plate outer peripheral portion 26 overlap each other in the Z direction.

The pressing member 50 is a member that is disposed in the arrangement portion 34 of the cover 30 and interferes with the pressing portion 28 from above to restrict the movement of the plate 20 in the Z direction. Although a specific shape of the pressing member 50 is not limited, in the example illustrated in FIG. 1A, the pressing member 50 has a screw shape having a head portion interfering with the pressing portion 28 and a screw groove screwed into the screw hole formed in the arrangement portion 34. The head portion of the pressing member 50 has a diameter corresponding to the substantially concave shape that is the substantially arc shape of the pressing portion 28. As illustrated in FIG. 1B, by screwing the pressing member 50 into the screw hole of the arrangement portion 34 in the state in which the plate 20 is placed in the frame portion 31 of the cover 30, the head portion of the pressing member 50 interferes with the upper surface of the pressing portion 28, and the movement of the plate 20 in the Z direction is restricted.

The fixing member 60 is a member that is inserted into the fixing hole 35 and fixes the sheet contactor socket 100 to the stiffener 80 via the substrate 70. The substrate 70 is a substantially plate-shaped member in which the sheet contactor socket 100 is attached to one surface of a plate-shaped portion 71 and the stiffener 80 is attached to the other surface of the plate-shaped portion 71. Through holes 72 are formed in the substrate 70 at a position corresponding to the fixing holes 35. The stiffener 80 is a substantially plate-shaped member that is attached to the substrate 70 on a side opposite the sheet contactor socket 100 and enhances the rigidity of the substrate 70. Screw holes 82 are formed in the support plate 81 of the stiffener 80 at positions corresponding to the fixing holes 35 of the cover 30.

As illustrated in FIG. 1C, the sheet contactor socket 100 is disposed on one surface of the substrate 70, the stiffener 80 is disposed on the other surface of the substrate 70, and the fixing member 60 is inserted into the through hole 72 and fastened to the screw hole 82, whereby the sheet contactor socket 100 and the stiffener 80 are fixed to the substrate 70.

Next, a configuration in which the cover 30 elastically supports the plate 20 will be described with reference to FIGS. 3A and 3B. As illustrated in FIG. 3A, one end of the spring member 40 is inserted into and locked to the locking portion 27, and is disposed between a back surface side of the plate outer peripheral portion 26 and the plate placement portion 33 in the spring accommodation portion 27a. In a state in which the semiconductor package 200 is not dropped onto the plate 20, the spring member 40 is in a state in which a biasing force thereof acts in the upper direction and presses the plate outer peripheral portion 26 of the plate 20 in the upper direction. The plate 20 is restricted from moving in the upper direction by the pressing members 50 disposed on the pressing portions 28 of the plate outer peripheral portion 26. Therefore, the upper surface of the plate outer peripheral portion 26 and the upper surface of the frame portion 31 have substantially the same height.

As illustrated in FIG. 3B, when the semiconductor package 200 is dropped onto the plate 20, the spring member 40 is in a contracted state since a force against the biasing force in the upper direction acts due to a load in the lower direction applied to the plate 20. Elastic deformation of the spring member 40 can absorb the impact caused by the drop of the semiconductor package 200, and the semiconductor package 200 can be placed in the accommodation portion 20a of the plate 20.

Next, the movement of the electrode 210 guided into the through hole 21a by the first guide portion 21b when the semiconductor package 200 is placed on the placement portion 21 will be described with reference to FIGS. 3C and 3D. FIG. 3C illustrates a state in which the electrode 210 of the semiconductor package 200 is inserted to be offset from the center of the through hole 21a. Further, FIG. 3D illustrates a state in which the electrode 210 inserted to be offset from the center of the through hole 21a moves along the first guide portion 21b and is aligned with the through hole 21a.

As illustrated in FIG. 3C, the electrode 210 of the semiconductor package 200 is brought into contact with the first guide portion 21b at a position offset from the center of the opening of the through hole 21a. At this time, since the first guide portion 21b has a tapered shape inclined toward the inside of the through hole 21a, a force in an arrow direction illustrated in FIGS. 3C and 3D acts on the electrode 210 at a contact point between the electrode 210 and the first guide portion 21b. Accordingly, as illustrated in FIG. 3D, the electrode 210 and the semiconductor package 200 are moved along the inclination of the first guide portion 21b, and the electrode 210 of the semiconductor package 200 is guided to a substantially center position of the through hole 21a. When the electrode 210 of the semiconductor package 200 is guided to the substantially center position of the through hole 21a by the first guide portion 21b, the electrode 210 comes into contact with the contact terminal 11 of the sheet contactor 10 disposed at the substantially center position and is electrically connected to the contact terminal 11.

As illustrated in FIG. 4A, the placement portion 21 is provided in the accommodation portion 20a of the plate 20 that accommodates the semiconductor package 200. The semiconductor package 200 dropped on the plate 20 is placed on the placement regions of the four placement portions 21. Note that the plurality of through holes 21a are arranged and formed such that a part of the plurality of contact terminals 11 of the sheet contactor 10 arranged at the lower side of the plate 20 are positioned on the substantially center positions of the through holes 21a. A part of the plurality of electrodes 210 of the semiconductor package 200 are inserted into the plurality of through holes 21a.

Here, each of the plurality of electrodes 210 of the semiconductor package 200 is guided by each of the plurality of through holes 21a to the substantially center position of the through hole 21a. Accordingly, the plurality of electrodes 210 of the semiconductor package 200 positioned above the opening 22 of the plate 20 also move toward an appropriate position of the sheet contactor 10 exposed from the opening 22. Each of the plurality of electrodes 210 is in contact with and electrically connected to each of the plurality of contact terminals 11 exposed from opening 22.

In the accommodation portion 20a of the plate 20, the placement portion 21 on which the semiconductor package 200 can be placed and the opening 22 as the non-placement portion on which the semiconductor package 200 is not placed are on substantially the same plane as the plane including the X direction and the Y direction. Accordingly, the plurality of contact terminals 11 supported in the support region 12a of the sheet body 12 of the sheet contactor 10 can be brought into contact with the electrodes 210 of the semiconductor package 200.

In the present embodiment, as illustrated in FIG. 4A, the plurality of through holes 21a are disposed at the four corners of the accommodation portion 20a having a substantially quadrilateral shape, but the present disclosure is not limited thereto. As long as the semiconductor package 200 can be stably placed, for example, the plurality of through holes 21a may be provided at least at two corners facing each other of the accommodation portion 20a having the substantially quadrilateral shape and may not be provided at the other two corners facing each other. Further, the plurality of through holes 21a may not be provided at the corners of the accommodation portion 20a. For example, the placement portion 21 having the plurality of through holes 21a in any one of the entire length or a part of each of the two sides along the X direction and the entire length or a part of each of the two sides along the Y direction may be disposed in the accommodation portion 20a having the substantially quadrilateral shape. Even in this case, by arranging and forming the plurality of through holes 21a described above, each of the electrodes 210 of the semiconductor package 200 can be guided to an appropriate position where each of the electrodes 210 can come into contact with each of the plurality of contact terminals 11 of the sheet contactor 10.

Of the placement region of the placement portion 21 and the non-placement region of the opening 22 serving as the non-placement portion in the accommodation portion 20a, the placement region of the placement portion 21 is smaller. By making the area of the placement portion 21 smaller than the area of the opening 22 that is the non-placement portion, it is possible to suppress processing defects such as strain in the placement portion 21 when forming the plurality of through holes 21a, compared to a case where the area of the placement portion 21 is larger than the area of the opening 22. Therefore, even when the thickness of the placement portion 21 is reduced, the plurality of through holes 21a and the first guide portions 21b can be arranged and formed in the placement portion 21. Accordingly, even if the protrusion amount of the contact terminal 11 from the sheet body 12 is small, the contact terminal 11 and the electrode 210 can be brought into good contact with each other.

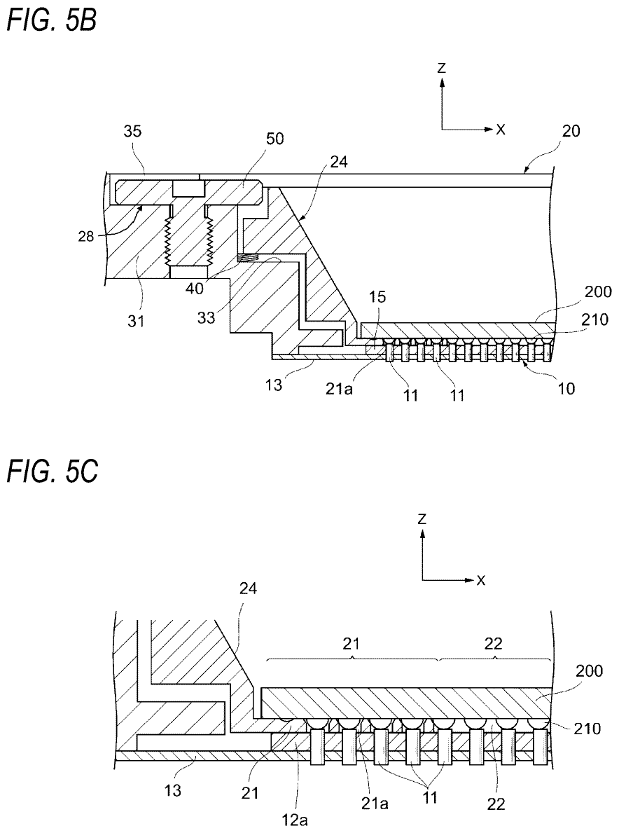

Next, a change in the state of the sheet contactor socket 100 when the semiconductor package 200 is placed on the plate 20 will be described with reference to FIGS. 5A and 5B. In FIGS. 5A and 5B, since an XZ cross section at a center position of the pressing member 50 is illustrated, only a part of a lower end side of the spring member 40 positioned deeper than the pressing member 50 is illustrated. FIG. 5A is a cross-sectional view of an embodiment of the sheet contactor socket 100 in the state in which the semiconductor package 200 is placed on the plate 20, and illustrates a state just before the semiconductor package 200 is dropped from above the plate 20 and placed on the plate 20. In FIG. 5A, the plate 20 floats in the upper direction with respect to the cover 30 by the elastic force of the spring member 40. In this state, the electrode 210 of the semiconductor package 200 is inserted into the through hole 21a of the placement portion 21 of the plate 20, but is not in contact with the contact terminal 11 of the sheet contactor 10.

FIG. 5B is a cross-sectional view of the embodiment of the sheet contactor socket 100 in the state in which the semiconductor package 200 is placed on the plate 20, and illustrates the sheet contactor socket 100 in a different state from that in FIG. 5A. FIG. 5B illustrates the state in which the semiconductor package 200 is placed on the plate 20 and the spring member 40 is compressed by the load of the semiconductor package 200. In this state, the plate 20 moves downward with the compression of the spring member 40, and the electrode 210 of the semiconductor package 200 comes into contact with the contact terminal 11 of the sheet contactor 10, so that the energization inspection can be performed. In order to make the plate 20 sink, the plate 20 and/or the semiconductor package 200 may be pressed by a handler device or the like.

As understood from FIGS. 5A and 5B, when the plate 20 is in the floating state, the pressing member 50 presses the pressing portion 28 of the plate 20 from above, but when the plate 20 is in the sinking state, the pressing member 50 is separated from the pressing portion 28 of the plate 20. As described above, when the cover 30 attempts to support the plate 20 only by the spring member 40, since the plate 20 is in the floating state and becomes unstable, the pressing member 50 is a member that restricts the plate 20 so as not to move upward while allowing the plate 20 to move downward.

FIG. 5C is an enlarged view illustrating contact portions between the electrodes 210 of the semiconductor package 200 of FIG. 5B and the contact terminals 11 of the sheet contactor 10. As illustrated in FIG. 5C, the contact terminals 11 of the sheet contactor 10 come into contact with the electrodes 210 of the semiconductor package 200 in both the placement portion 21 of the plate 20 and the opening 22.

Embodiments and modifications of the present invention have been described above with reference to the drawings, but these embodiments and modifications are examples of the present invention, and various configurations other than those described above can also be used.

According to the present disclosure, a sheet contactor socket of the following aspects is provided.

### (Aspect 1)

A sheet contactor socket according to Aspect 1 includes:
a plate positioned on an upper side of a sheet contactor having a plurality of contact terminals and having an accommodation portion that is able to accommodate a semiconductor package having a plurality of contact portions in contact with the plurality of contact terminals, respectively; and
a cover configured to elastically support the plate, in which
the accommodation portion includes:
   a placement portion on which the semiconductor package is able to be placed and that has a guiding portion that guides contact portions of the plurality of contact portions to a position where the plurality of contact portions and the plurality of contact terminals are able to be brought into contact with each other; and
   a non-placement portion on which the semiconductor package is not placed, and
a placement region of the placement portion in the accommodation portion is smaller than a non-placement region of the non-placement portion on which the semiconductor package is not placed.

According to the above-described aspect, when the semiconductor package is placed on the plate, since the plate is elastically supported by the cover, the impact is absorbed by the elasticity, and the impact received by the semiconductor package is reduced. Further, since the placement region of the placement portion is smaller than the non-placement region, processing defects can be suppressed even when the thickness of the placement portion is reduced.

### (Aspect 2)

In the sheet contactor socket according to Aspect 2, the non-placement region has an opening, and contact terminals of the plurality of contact terminals and contact portions of the plurality of contact portions are able to be brought into contact with each other also in the opening.

According to the above-described aspect, since the contact terminal of the sheet contactor and the contact portion of the semiconductor package are brought into contact with each other via the opening even in the non-placement region, it is possible to reduce the area of the placement portion and suppress the processing defects.

### (Aspect 3)

In the sheet contactor socket according to Aspect 3, the placement portion includes a first guide portion configured to guide the plurality of contact portions of the semiconductor package.

According to the above-described aspect, when a pin of the semiconductor package is inserted into a hole of the placement portion of the plate, the alignment can be facilitated.

### (Aspect 4)

In the sheet contactor socket according to Aspect 4, the guiding portion includes a second guide portion configured to guide the semiconductor package to the placement portion.

According to the above-described aspect, when the semiconductor package is placed on the plate of the sheet contactor socket, the semiconductor package can be easily aligned with the placement portion of the plate.

### (Aspect 5)

In the sheet contactor socket according to Aspect 5, an area of the placement portion of the plate is 0.1 times or less an area of the non-placement portion.

According to the above-described aspect, since the area of the placement portion is small, the placement portion of the plate can be easily processed.

### (Aspect 6)

In the sheet contactor socket according to Aspect 6, the semiconductor package has a quadrilateral shape, and at least two corner portions of the semiconductor package are able to be placed on the placement portion of the plate.

According to the above-described aspect, even if the area of the placement portion is small, the semiconductor package is easily supported by the placement portion.

### (Aspect 7)

In the sheet contactor socket according to Aspect 7, the plurality of contact terminals of the sheet contactor include conductive particles.

According to the above-described aspect, since the movement of the sheet contactor in an upper-lower direction is more limited, advantageous effects of this embodiment can be easily obtained.

### (Aspect 8)

In the sheet contactor socket according to Aspect 8, the cover elastically supports the plate by a spring.

According to the above-described aspect, when the semiconductor package is placed on the plate, the impact applied to the semiconductor package by the spring member can be significantly reduced.

### (Aspect 9)

A sheet contactor socket according to Aspect 9 includes:
a sheet contactor having a plurality of contact terminals;
a plate having an accommodation portion that is able to accommodate a semiconductor package having a plurality of contact portions in contact with the plurality of contact terminals, respectively; and
a cover configured to elastically support the plate, in which
the accommodation portion includes:
   a placement portion on which the semiconductor package is able to be placed and that has a guiding portion that guides contact portions of the plurality of contact portions to a position where the plurality of contact portions and the plurality of contact terminals are able to be brought into contact with each other; and
   a non-placement portion on which the semiconductor package is not placed, and
a placement region of the placement portion in the accommodation portion is smaller than a non-placement region of the non-placement portion on which the semiconductor package is not placed.

According to the above-described aspect, when the semiconductor package is placed on the plate, since the plate is elastically supported by the cover, the impact is absorbed by the elasticity, and the impact received by the semiconductor package is reduced. Further, since the placement region of the placement portion is smaller than the non-placement region, processing defects can be suppressed even when the thickness of the placement portion is reduced.

1. A sheet contactor socket, comprising:
a plate positioned on an upper side of a sheet contactor having a plurality of contact terminals and having an accommodation portion that is able to accommodate a semiconductor package having a plurality of contact portions in contact with the plurality of contact terminals, respectively; and
a cover configured to elastically support the plate, wherein
the accommodation portion includes:
a placement portion on which the semiconductor package is able to be placed and that has a guiding portion that guides contact portions of the plurality of contact portions to a position where the plurality of contact portions and the plurality of contact terminals are able to be brought into contact with each other; and
a non-placement portion on which the semiconductor package is not placed, and
a placement region of the placement portion in the accommodation portion is smaller than a non-placement region of the non-placement portion on which the semiconductor package is not placed.

2. The sheet contactor socket according to claim 1, wherein
the non-placement region has an opening, and contact terminals of the plurality of contact terminals and contact portions of the plurality of contact portions are able to be brought into contact with each other also in the opening.

3. The sheet contactor socket according to claim 1, wherein
the placement portion includes a first guide portion configured to guide the plurality of contact portions of the semiconductor package.

4. The sheet contactor socket according to claim 1, wherein
the guiding portion includes a second guide portion configured to guide the semiconductor package to the placement portion.

5. The sheet contactor socket according to claim 1, wherein
an area of the placement portion of the plate is 0.1 times or less an area of the non-placement portion.

6. The sheet contactor socket according to claim 1, wherein
the semiconductor package has a quadrilateral shape, and at least two corner portions of the semiconductor package are able to be placed on the placement portion.

7. The sheet contactor socket according to claim 1, wherein
the plurality of contact terminals of the sheet contactor include conductive particles.

8. The sheet contactor socket according to claim 1, wherein
the cover elastically supports the plate by a spring.

9. A sheet contactor socket, comprising:
a sheet contactor having a plurality of contact terminals;
a plate having an accommodation portion that is able to accommodate a semiconductor package having a plurality of contact portions in contact with the plurality of contact terminals, respectively; and
a cover configured to elastically support the plate, wherein
the accommodation portion includes:
a placement portion on which the semiconductor package is able to be placed and that has a guiding portion that guides contact portions of the plurality of contact portions to a position where the plurality of contact portions and the plurality of contact terminals are able to be brought into contact with each other; and
a non-placement portion on which the semiconductor package is not placed, and
a placement region of the placement portion in the accommodation portion is smaller than a non-placement region of the non-placement portion on which the semiconductor package is not placed.
